(19) United States
(12) Patent Application Publication
(10) Pub. No.: US 2026/0256002 A1
(43) Pub. Date: Aug. 27, 2026

(54) LOWER COST POWER MODULE WITH HIGHER CONFIGURATION FLEXIBILITY

(71) Applicant: University of Central Florida Research Foundation, Inc., Orlando, FL (US)

(72) Inventor: Qichen Yang, Orlando, FL (US)

(73) Assignee: University of Central Florida Research Foundation, Inc., Orlando, FL (US)

(21) Appl. No.: 19/542,281

(22) Filed: Feb. 17, 2026

Related U.S. Application Data
(60) Provisional application No. 63/763,018, filed on Feb. 25, 2025.

(51) Int. Cl. H10W 70/692; H10D 80/20; H10D 80/30; H10W 40/00; H10W 40/20; H10W 42/60; H10W 70/05; H10W 70/60; H10W 70/63; H10W 70/695; H10W 74/10; H10W 90/00; H10W 90/10; H10W 90/20; H10W 90/22

(52) U.S. Cl. CPC H10W 70/692; H10D 80/251; H10D 80/30; H10W 40/03; H10W 40/233; H10W 42/60; H10W 70/095; H10W 70/611; H10W 70/635; H10W 70/695; H10W 74/114; H10W 90/10; H10W 90/22; H10W 90/291; H10W 90/753

(57) ABSTRACT

A lower cost power module with a higher configuration flexibility is provided. The lower cost power module with a higher configuration flexibility includes a polymer-ceramic composite substrate, a fully controlled power semiconductor device, and electrical circuitry configured to absorb and/or dissipate electrical energy. Optionally, the fully controlled power semiconductor device and the electrical circuitry configured to absorb and/or dissipate electrical energy are mounted on the same surface of the polymer-ceramic composite substrate. The polymer-ceramic composite substrate includes a first surface and a second surface opposite the first surface. A fully controlled power semiconductor device is mounted on the first surface. The fully controlled power semiconductor device includes an electrical control terminal, a first power terminal, and a second power terminal. The electrical circuitry configured to absorb and/or dissipate electrical energy is electrically connected to the first and the second power terminals of a fully controlled power semiconductor device.

### CROSS-REFERENCE TO RELATED APPLICATIONS

This application claims benefit of United States Provisional Patent Application No. 63/763,018 filed on Feb. 25, 2025, and titled “LOWER COST POWER MODULE WITH HIGHER CONFIGURATION FLEXIBILITY”, the contents of which are incorporated herein in their entirety.

### BACKGROUND

High voltage power semiconductor switching devices in high power modules typically operate continuously for a long period of time. Thus, the high voltage power semiconductor switching devices generate significant heat which must be dissipated.

Conventionally, in a high voltage power module, such high voltage power semiconductor switching devices are mounted on a ceramic substrate which conveys heat away from the high voltage power semiconductor switching devices to a heat sink, e.g., a metal heat sink. It is difficult to modify the ceramic substrate. For example, hole(s) may need to be formed through the ceramic substrate with which to make an electrically conductive through via hole configured to conduct an electrical signal and/or electrical power. However, forming such hole(s), risks forming cracks in the ceramic substrate. Such cracks may cause ceramic substrate to fracture in one or more pieces and, thus, cause failure of the high voltage power module. To diminish this problem, typically the high voltage power semiconductor switching devices are mounted on only one surface or side of the ceramic substrate which can undesirably increase an area or volume of the high voltage power module. Also, the ceramic substrate and the heat sink are expensive.

Further, voltage and/or current suppression circuitry, outside of the high voltage power module, is electrically connected across an output of one or more high voltage power semiconductor switching devices. The voltage and/or current suppression circuitry is conventionally located outside of the high voltage power module. In the case of a circuit breaker, the voltage and/or current suppression circuitry is used to absorb electrical power when the circuit breaker is tripped. Electrical conductor(s) electrically connecting the voltage and/or current suppression circuitry to the high voltage power semiconductor switching devices have a parasitic inductance which causes a voltage transient when current through the high voltage power semiconductor switching device(s) varies. Such a voltage transient can damage the high voltage power semiconductor switching device(s).

### SUMMARY

In some aspects, the techniques described herein relate to a lower cost power module with a higher configuration flexibility, including: a polymer-ceramic composite substrate, wherein the polymer-ceramic composite substrate including a first surface and a second surface opposite the first surface; one or more fully controlled power semiconductor devices each of which is on the first surface, wherein each fully controlled power semiconductor device includes an electrical control terminal, a first power terminal, and a second power terminal; and one or more electrical circuits configured to absorb and/or dissipate electrical energy each of which is on the first surface, wherein each electrical circuit configured to absorb and/or dissipate the electrical energy is electrically connected to the first and the second power terminals of a fully controlled power semiconductor device.

In some aspects, the techniques described herein relate to a method of making a lower cost power module with higher configuration flexibility, the method including: mounting, on a first surface of a polymer-ceramic substrate, a fully controlled power semiconductor device; mounting, on the first surface of the polymer-ceramic substrate, electrical circuitry configured to absorb and/or dissipate electrical energy; and electrically connecting the fully controlled power semiconductor device to the electrical circuitry configured to absorb and/or dissipate the electrical energy.

### BRIEF DESCRIPTION OF THE DRAWINGS

Embodiments of the present invention can be more easily understood and further advantages and uses thereof more readily apparent, when considered in view of the description of the preferred embodiments and the following figures in which:

FIG. 1 illustrates a high voltage electrical system of one or more lower cost power modules with higher configuration flexibility according to embodiments of the invention.

FIG. 2 illustrates a top view of one embodiment of a lower cost power module with higher configuration flexibility according to embodiments of the invention.

FIG. 3A illustrates a cross-sectional diagram of the embodiment of a lower cost power module with higher configuration flexibility according to embodiments of the invention.

FIG. 3B illustrates one embodiment of another high voltage electrical system of one or more lower cost power modules with higher configuration flexibility according to embodiments of the invention.

FIG. 4 illustrates a cross-sectional diagram of another embodiment of a lower cost power module with higher configuration flexibility according to embodiments of the invention.

FIG. 5 illustrates a flow diagram of one embodiment of a method of making a lower cost power module with higher configuration flexibility according to embodiments of the invention.

In accordance with common practice, the various described features are not drawn to scale but are drawn to emphasize features relevant to the present invention. Reference characters denote like elements throughout figures and text.

### DETAILED DESCRIPTION

In the following detailed description, reference is made to the accompanying drawings that form a part hereof, and in which is shown by way of specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the scope of the present invention. The following detailed description is, therefore, not to be taken in a limiting sense.

Techniques are disclosed for a lower cost power module with higher configuration flexibility which has discontinuous, and possibly a lower time averaged, thermal load than a conventional high voltage power module, e.g., because it does not operate continuously. The lower cost power module with higher configuration flexibility, for example, operates up to thousands of volts DC.

One example of the lower cost power module with higher configuration flexibility, is a direct current circuit breaker. The DC circuit breaker needs only to dissipate heat for a relatively brief time when an excessive current level and/or voltage level causes the DC circuit breaker to trip.

Because it generates substantially less heat, the lower cost power module with higher configuration flexibility does not need to be constructed with the same heat dissipating material as a conventional high voltage power module. The high voltage power module, according to embodiments of the invention, can be made with a polymer-ceramic composite substrate, rather than a ceramic substrate. The polymer-ceramic composite substrate means a polymer matrix with inorganic ceramic fillers, and optionally an organic hydrocarbon polymer matrix. An example of a polymer-ceramic composite substrate is Rogers Corporation RO4350B Laminate. A polymer-ceramic composite substrate is cheaper, easier from which to remove material (e.g., to form a through hole), and/or has a higher reliability due to a lower probability of cracking. Further, no heat sink is needed. Additionally, voltage suppression circuit(s) can be mounted with fully controlled power semiconductor device(s) on the polymer-ceramic composite substrate which further increases the reliability, due to diminished transient voltage levels arising from a shorter electrical connection between components, of the lower cost power module with higher configuration flexibility.

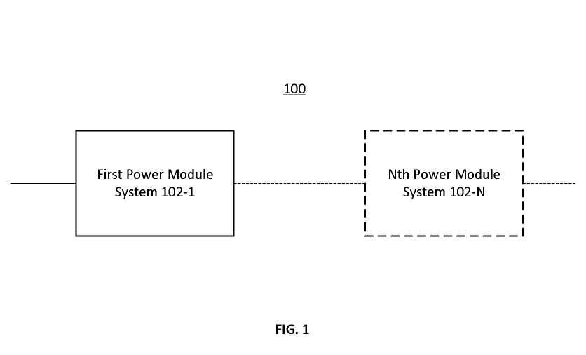

FIG. 1 illustrates a high voltage electrical system 100 of one or more lower cost power modules with higher configuration flexibility according to embodiments of the invention. The high voltage electrical system 100 includes one or more, e.g., N, lower cost power modules with higher configuration flexibility 102-1, 102-N which are electrically connected, for example, serially. N is an integer greater than zero.

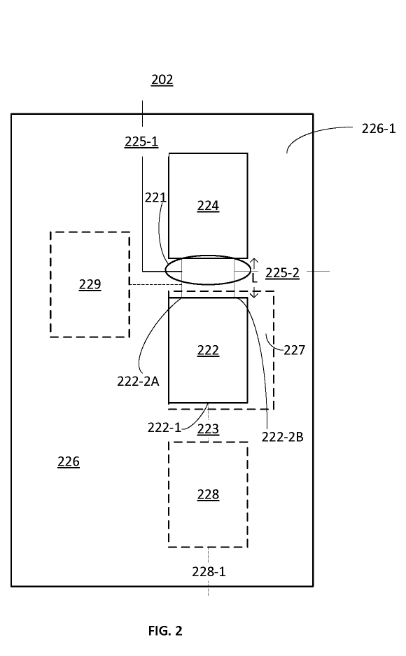

FIG. 2 illustrates a top view of one embodiment of a lower cost power module with higher configuration flexibility 202 according to embodiments of the invention. Element numbers in FIG. 2 which are similar to those in FIG. 1 and begin with a two rather than a one represent a corresponding component or signal described with respect to FIG. 1. The lower cost power module with higher configuration flexibility 202 includes a first electrical terminal 225-1 and a second electrical terminal 225-2 each of which is located as illustrated in FIG. 2 for pedagogical purposes; however, the first electrical terminal 225-1 and/or the second electrical terminal 225-2 may be located elsewhere.

The lower cost power module with higher configuration flexibility 202 includes a polymer-ceramic composite substrate 226 which has a first surface 226-1. A fully controlled power semiconductor device 222 is on the first surface 226-1 of the polymer-ceramic composite substrate 226. Optionally the fully controlled power semiconductor device 222 is affixed, e.g., by an adhesive, solder, sinter, and/or mechanical attachment devices (e.g., screws), to the polymer-ceramic composite substrate 226, e.g., the first surface thereof 226-1. The fully controlled power semiconductor device 222 has a device electrical control terminal 222-1, a first device power terminal 222-2A, and a second device power terminal 222-2B.

A fully controlled power semiconductor device 222 means a power semiconductor device that can be turned both on and off completely by a control signal applied to the device electrical control terminal 222-1; as a result, electrical power flowing between the first and the second device power terminals 222-2A, 222-2B of the fully controlled power semiconductor device 222 can be precisely controlled. Optionally, the fully controlled power semiconductor device 222 has an output breakdown voltage of up to thousands of volts DC. Non-limiting examples of a fully controlled power semiconductor device 222 include a metal oxide semiconductor field effect transistor (MOSFET), an insulated gate bipolar transistor (IGBT), a metal oxide semiconductor controlled thyristor (MCT), a gate turn-off thyristor (GTO), and an integrated gate commutate thyristor (IGCT).

Each of the first and the second device power terminals 222-2A, 222-2B of the fully controlled power semiconductor device 222 is electrically connected, by electrical conductor(s) 221, to an electrical circuit 224 configured to absorb and/or dissipate electrical energy. Optionally the electrical circuit 224 configured to absorb and/or dissipate electrical energy is affixed, e.g., by an adhesive, solder, sinter, and/or mechanical attachment devices (e.g., screws), to the polymer-ceramic composite substrate 226, e.g., the first surface 226-1 thereof. Each of the electrical conductor(s) 221 and the electrical circuit 224 configured to absorb and/or dissipate electrical energy are on the first surface 226-1 of the polymer-ceramic composite substrate 226. Optionally, the electrical conductor(s) 221 includes bond wire(s) and/or bond ribbon(s); however, other forms of electrical conductors may be used, for example, copper clips.

Because the fully controlled power semiconductor device 222 and the electrical circuit 224 configured to absorb and/or dissipate electrical energy are both on the polymer-ceramic composite substrate 226, a length L of the electrical conductor(s) 221 is significantly reduced in comparison to prior art techniques. Because the length L of the electrical conductor(s) 221 is significantly reduced, the parasitic inductance of the electrical conductor(s) 221, and any voltage transients created by such inductance and changes in current in the electrical conductor(s) 221, are also substantially reduced. Optionally, the electrical circuit 224 configured to absorb and/or dissipate electrical energy consists of a transient voltage suppressor (TVS) diode, a metal oxide varistor (MOV), an avalanche diode, a Zener diode, and/or a gas discharge tube.

Optionally, the lower cost power module with higher configuration flexibility 202 further includes a heat absorber 227, e.g., which includes phase-change material(s), high-specific-heat material(s), aluminum plate(s), and/or molybdenum plate(s), covering, at least partially, the fully controlled power semiconductor device 222, e.g., one or more surfaces thereof. For example, the optional heat absorber 227 covers the top and/or one or more sides of the fully controlled power semiconductor device 222. The optional heat absorber 227 is configured to dissipate heat from the fully controlled power semiconductor device 222.

Optionally, the lower cost power module with higher configuration flexibility 202 also includes a driver circuit 228, on the first surface 226-1, configured to receive a first control signal 228-1, e.g., an electrical or an optical signal, and convert it to a second control, or a gate drive, signal 223 which, e.g., is an electrical signal. The first control signal 228-1, and thus the second control signal 223, is configured to regulate electrical power flowing through the output (i.e., the first and the second device power terminals 222-2A, 222-2B) of the fully controlled power semiconductor device 222. Signals described herein, e.g., the second control signal 223, may be provided with respect to another terminal, e.g., electrical ground, (not shown).

Optionally, the lower cost power module with higher configuration flexibility 202 also includes another circuit 229 on the first surface 226-1. Optionally, the other circuit 229 is a voltage lifting circuit. Optionally, the first electrical terminal 225-1 may be electrically connected to or through the other circuit 229.

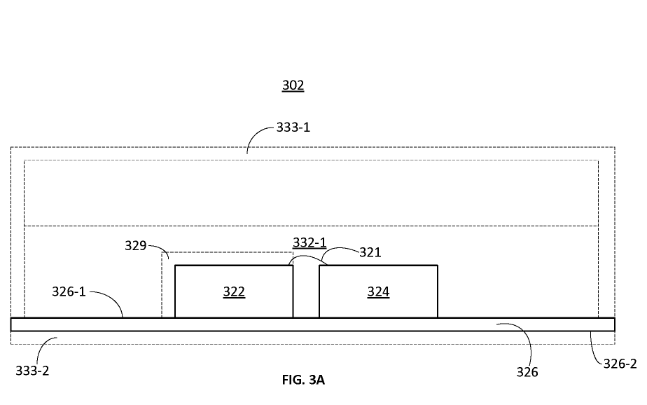

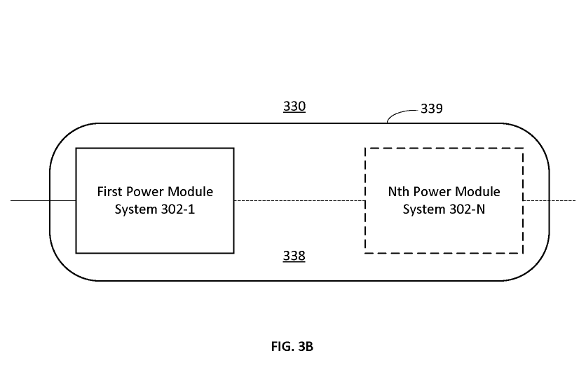

FIG. 3A illustrates a cross-sectional diagram of the embodiment of a lower cost power module with higher configuration flexibility 302 according to embodiments of the invention. Element numbers in FIG. 3A which are similar to those in FIGS. 1 and/or 2 and begin with a three rather than a one or a two represent a corresponding component or signal described with respect to FIGS. 1 and/or 2. FIG. 3A illustrates the optional bond wire(s) and/or bond ribbon(s) 321 described elsewhere herein; however other electrical connector types may be used in the alternative.

The lower cost power module with higher configuration flexibility 302 optionally includes a first potting 332-1. Each potting described herein is used: (a) to exclude water, moisture, and/or corrosive agents from the lower cost power module with higher configuration flexibility 302 (for example, the fully controlled power semiconductor device 222, the electrical conductor(s) 221, the electrical circuit 224 configured to absorb and/or dissipate electrical energy, the optional driver circuit 228, the optional other circuit 229, the optional bottom mounted (or other) electrical circuit(s) 442, and/or the optional heat absorber 227), (b) to increase resistance, of the lower cost power module with higher configuration flexibility 302, to shocks and vibrations, and/or (c) to prevent electric discharge (such as partial discharge) which could damage the lower cost power module with higher configuration flexibility 302 (for example, the fully controlled power semiconductor device 222, the electrical conductor(s) 221, the electrical circuit 224 configured to absorb and/or dissipate electrical energy, the optional driver circuit 228, the optional other circuit 229, and/or the optional heat absorber 227). Optionally, the potting described herein is a solid or gelatinous compound, e.g., thermosetting plastics, epoxy, or silicone gel. The bottom mounted electrical circuit(s) 442 provide additional functionality.

FIG. 3B illustrates one embodiment of another high voltage electrical system 330 of one or more lower cost power modules with higher configuration flexibility according to embodiments of the invention. Element numbers in FIG. 3B which are similar to those in FIGS. 1 and/ or 2 and begin with a three rather than a one or a two represent a corresponding component or signal described with respect to FIGS. 1 and/ or 2.

If, for example, the optional first housing 333-1, an optional second housing 433-3, the optional baseplate 333-2, the optional first potting 332-1, and/or the optional second potting 432-2 are not used, then optionally one or more of the lower cost power module with higher configuration flexibility may be immersed in liquid insulation material 338, e.g., mineral oil,

contained within a tank 339. The liquid insulation material 338 described herein is used: (a) to exclude water, moisture, and/or corrosive agents from the lower cost power module with higher configuration flexibility (for example, the fully controlled power semiconductor device 222, the electrical conductor(s) 221, the electrical circuit 224 configured to absorb and/or dissipate electrical energy, the optional driver circuit 228, the optional other circuit 229, the optional bottom mounted circuit(s) 442, and/or the optional heat absorber 227), (b) to prevent electric discharge (such as partial discharge), which could damage the lower cost power module with higher configuration flexibility (for example, the fully controlled power semiconductor device 222, the electrical conductor(s) 221, the electrical circuit 224 configured to absorb and/or dissipate electrical energy, the optional driver circuit 228, the optional other circuit 229, and/or the optional heat absorber 227), (c) to provide electrical insulation, and/or (d) to cool down the lower cost power module with higher configuration flexibility (for example, the fully controlled power semiconductor device 222, the electrical conductor(s) 221, the electrical circuit 224 configured to absorb and/or dissipate electrical energy, the optional driver circuit 228, the optional other circuit 229, and/or the optional heat absorber 227) by providing heat dissipation into the liquid insulation material 338.

Returning to FIG. 3A, the lower cost power module with higher configuration flexibility 302 optionally includes a baseplate 333-2 on, at least a portion of, a second surface 326-2 of the polymer-ceramic composite substrate 326. Optionally, the baseplate 333-2 is a thermally conductive material configured to extract heat from the lower cost power module with higher configuration flexibility 302, and/or to enclose the second surface 326-2 of the polymer-ceramic composite substrate 326. The second surface 326-2 is opposite the first surface 326-1. Optionally, the baseplate 333-2 includes metal or a semiconductor.

The lower cost power module with higher configuration flexibility 302 optionally includes a first housing 333-1 configured to enclose, at least a portion of the first surface 326-1 and which optionally excludes water, moisture, and/or corrosive agents from the lower cost power module with higher configuration flexibility 302 (for example, the fully controlled power semiconductor device 222, the electrical conductor(s) 221, the electrical circuit 224 configured to absorb and/or dissipate electrical energy, the optional driver circuit 228, the optional other circuit 229, and/or the optional heat absorber 227). Each housing described herein may be on a surface of the polymer-ceramic composite substrate 226 and/or the optional baseplate 333-2. Optionally, each housing described herein is an electrical insulator.

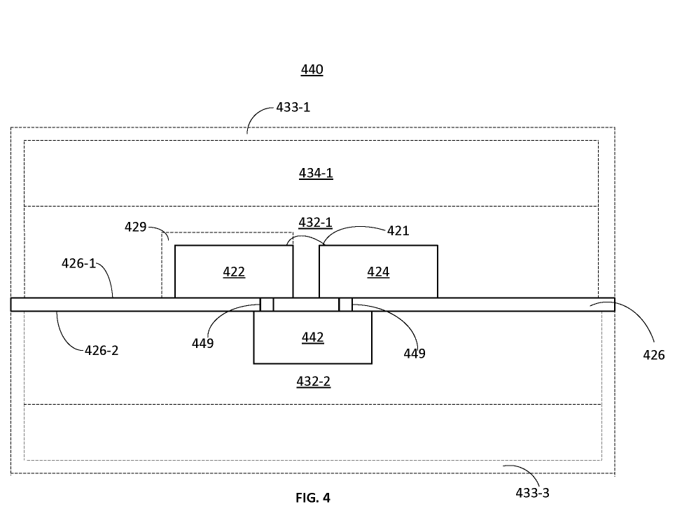

FIG. 4 illustrates a cross-sectional diagram of another embodiment of a lower cost power module with higher configuration flexibility 440 according to embodiments of the invention. Element numbers in FIG. 4 which begin with a four rather than a one, two, or three and are similar to those in FIGS. 1, 2, 3A, and/or 3B represent a corresponding component or signal described with respect to FIGS. 1, 2, 3A and/or 3B.

In the lower cost power module with higher configuration flexibility 440 of FIG. 4, one or more bottom mounted circuits 442 are optionally on the second surface 426-2. The optional bottom mounted circuit(s) 442 may optionally include the driver circuit 228 and/or the other circuit 229. The second surface 426-2 is optionally enclosed by a second potting 432-2 and/or a second housing 433-3. Because the polymer-ceramic composite substrate is more easily modified, e.g., can have through hole(s) inserted in it more easily and with less risk of substrate fracture. Thus, one or more optional bottom mounted circuits 442 on the second surface 426-2 (that are electrically connected through electrically conductive through via hole(s) 449 in the polymer-ceramic composite substrate 426) to at least one fully controlled power semiconductor device 422 and/or at least one electrical circuit 424 configured to absorb and/or dissipate electrical energy. As a result, embodiments of the invention have higher configuration flexibility than the prior art. FIG. 4 illustrates the optional bond wire(s) or bond ribbon(s) 421 described elsewhere herein. Optionally, each of the electorally conductive through via hole(s) 449 provide an electrical connection between the first surface 426-1 to the second surface 426-2.

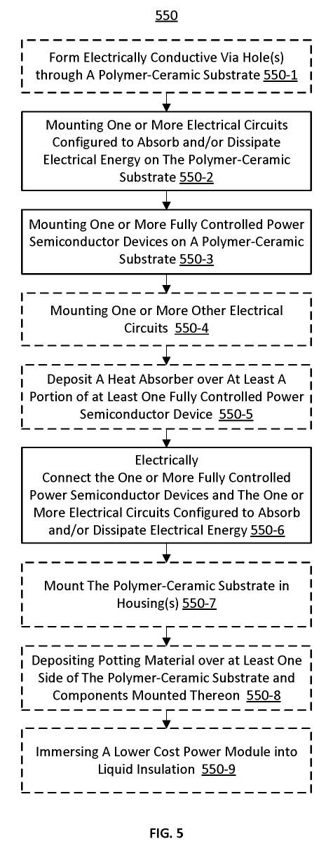

FIG. 5 illustrates a flow diagram of one embodiment of a method 550 of making a lower cost power module with higher configuration flexibility according to embodiments of the invention. To the extent the methods herein are described herein as being implemented with the apparatus illustrated in one or more of FIGS. 1-4, it is to be understood that other embodiments can be implemented in other ways. Techniques described with respect to the embodiments illustrated by one or more of FIGS. 1-4 may be applicable to the methods described herein.

The blocks of the flow diagrams herein have been arranged in a generally sequential manner for ease of explanation; however, it is to be understood that this arrangement is merely exemplary, and it should be recognized that the processing associated with the methods (and the blocks shown in the Figures) can occur in a different order (for example, where at least some of the processing associated with the blocks is performed in parallel and/or in an event-driven manner).

In optional block 550-1, at least one electrically conductive via hole is formed through, e.g., a first surface to a second surface, of a polymer-ceramic substrate. Thus, optionally, each electrically conductive via hole provides an electrical connection between such first and such second surfaces.

In block 550-2, one or more an electrical circuits configured to absorb and/or dissipate electrical energy are mounted on the first surface of a polymer-ceramic substrate. Optionally each fully controlled power semiconductor device is affixed, e.g., by an adhesive, solder, sinter, and/or mechanical attachment devices (e.g., screws), to the first surface of the polymer-ceramic composite substrate.

In block 550-3, one or more fully controlled power semiconductor devices are mounted on the first surface of a polymer-ceramic substrate. Optionally each fully controlled power semiconductor device is affixed, e.g., by an adhesive, solder, sinter, and/or mechanical attachment devices (e.g., screws), to the first surface of the polymer-ceramic composite substrate.

In optional block 550-4, one or more other electrical circuits are mounted on the second surface of the polymer-ceramic substrate. The one or more other electrical circuits are described elsewhere herein. Optionally each other electrical circuit is affixed, e.g., by an adhesive, solder, sinter, and/or mechanical attachment devices (e.g., screws), to the first surface of the polymer-ceramic composite substrate.

The second surface is opposite the first surface. At least one of the other electrical circuits is electrically connected, through at least one of the electrically conductive via holes, to a fully controlled power semiconductor device and/or an electrical circuits configured to absorb and/or dissipate electrical energy.

In optional block 550-5, a heat absorber is deposited over at least a portion of at least one fully controlled power semiconductor device. The heat absorber is described elsewhere herein.

In block 550-6, the one or more fully controlled power semiconductor devices are electrically connected to the one or more an electrical circuits configured to absorb and/or dissipate electrical energy. Optionally, such electrical connection is made with electrical connector(s), e.g., bond wire(s) and/or bond ribbon(s).

In optional block 550-7, the polymer-ceramic substrates, and thus components affixed thereto, are mounted in at least one housing. The housing(s) are described elsewhere herein.

In optional block 550-8, potting material is deposited over at least one side of the polymer-ceramic material and the components affixed thereto. Such potting material is further discussed elsewhere herein.

In optional block 550-9, the lower cost power module with increased flexibility is immersed in liquid insulation. Such liquid insulation is discussed further in elsewhere herein.

Terms of relative position as used in this application are defined based on a plane parallel to the conventional plane or working surface of a material (e.g. a layer or a substrate), regardless of orientation. Terms such as “on,” “higher,” “lower,” “over,” “top,” and “under” are defined with respect to the conventional plane or working surface being on the top surface of a layer or substrate, regardless of orientation.

### Exemplary Embodiments

Example 1 is a lower cost power module with a higher configuration flexibility, comprising: a polymer-ceramic composite substrate, wherein the polymer-ceramic composite substrate including a first surface and a second surface opposite the first surface; one or more fully controlled power semiconductor devices each of which is on the first surface, wherein each fully controlled power semiconductor device includes an electrical control terminal, a first power terminal, and a second power terminal; and one or more electrical circuits configured to absorb and/or dissipate electrical energy each of which is on the first surface, wherein each electrical circuit configured to absorb and/or dissipate the electrical energy is electrically connected to the first and the second power terminals of a fully controlled power semiconductor device.

Example 2 is the lower cost power module with the higher configuration flexibility of Example 1, wherein each electrical circuit configured to absorb and/or dissipate the electrical energy consists of a transient voltage suppressor diode, a metal oxide varistor, an avalanche diode, a Zener diode, and/or a gas discharge tube.

Example 3 is the lower cost power module with the higher configuration flexibility of one of Examples 1-2, wherein the one or more fully controlled power semiconductor devices include a metal oxide semiconductor field effect transistor (MOSFET), an insulated gate bipolar transistor (IGBT), a metal oxide semiconductor controlled thyristor (MCT), a gate turn-off thyristor (GTO), and/or an integrated gate commutate thyristor (IGCT).

Example 4 is the lower cost power module with the higher configuration flexibility of one of Examples 1-3, wherein the polymer-ceramic composite substrate comprises Rogers Corporation RO4350B Laminate.

Example 5 is the lower cost power module with the higher configuration flexibility of one of Examples 1-4, wherein the lower cost power module with the higher configuration flexibility is covered by potting material.

Example 6 is the lower cost power module with the higher configuration flexibility of Example 5, wherein the potting material comprises a solid or gelatinous compound.

Example 7 is the lower cost power module with the higher configuration flexibility of one of Examples 1-6, wherein the lower cost power module with the higher configuration flexibility is immersed in liquid insulation material.

Example 8 is the lower cost power module with the higher configuration flexibility of Example 7, wherein the liquid insulation material comprises mineral oil.

Example 9 is the lower cost power module with the higher configuration flexibility of one of Examples 1-8, further comprising a heat absorber covering, at least partially, at least one of the one or more fully controlled power semiconductor devices.

Example 10 is the lower cost power module with the higher configuration flexibility of Example 9, wherein the heat absorber comprises a phase-change material, a high-specific-heat material, aluminum, and/or molybdenum.

Example 11 is the lower cost power module with the higher configuration flexibility of one of Examples 1-10, further comprising: another electrical circuit on the second surface; and an electrically conductive via hole, through the first and the second surfaces, which is configured to electrically connect the other electrical circuit with the fully controlled power semiconductor device and/or with an electrical circuit configured to absorb and/or dissipate the electrical energy.

Example 12 is a method of making a lower cost power module with higher configuration flexibility, the method comprising: mounting, on a first surface of a polymer-ceramic substrate, a fully controlled power semiconductor device; mounting, on the first surface of the polymer-ceramic substrate, electrical circuitry configured to absorb and/or dissipate electrical energy; and electrically connecting the fully controlled power semiconductor device to the electrical circuitry configured to absorb and/or dissipate the electrical energy.

Example 13 is the method of Example 12, further comprising depositing a heat absorber over at least a portion of at least one fully controlled power semiconductor device.

Example 14 is the method of one of Examples 12-13, further comprising immersing the lower cost power module with the higher configuration flexibility in liquid insulation.

Example 15 is the method of one of Examples 12-14, further comprising: forming at least one electrically conductive via hole through the polymer-ceramic substrate from the first surface to a second surface of the polymer-ceramic substrate, wherein the first surface is opposite the second surface; and mounting one or more other electrical circuits on the second surface of the polymer-ceramic substrate, wherein at least one other electrical circuit is electrically connected, through one or more electrically conductive via holes, to the fully controlled power semiconductor device and/or the electrical circuitry configured to absorb and/or dissipate the electrical energy.

Example 16 is the method of Example 15, further comprising depositing a heat absorber over at least a portion of at least one fully controlled power semiconductor device.

Example 17 is the method of one of Examples 15-16, further comprising immersing the lower cost power module with the higher configuration flexibility in liquid insulation.

Example 18 is the method of one of Examples 15-17, further comprising: depositing a heat absorber over at least a portion of at least one fully controlled power semiconductor device; mounting the polymer-ceramic substrate in at least one housing; and depositing potting material over at least one side of the polymer-ceramic substrate and components thereon.

Example 19 is the method of Example 18, further comprising immersing the lower cost power module with the higher configuration flexibility in liquid insulation.

Example 20 is the method of Example 12, wherein electrically connecting the fully controlled power semiconductor device to the electrical circuitry configured to absorb and/or dissipate the electrical energy comprises electrically connecting, with one or more wire bonds and/or bond ribbons, the fully controlled power semiconductor device to the electrical circuitry configured to absorb and/or dissipate the electrical energy.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the present invention. Therefore, it is manifestly intended that this invention be limited only by the claims and the equivalents thereof.

What is claimed is:

1. A lower cost power module with a higher configuration flexibility, comprising:
a polymer-ceramic composite substrate, wherein the polymer-ceramic composite substrate including a first surface and a second surface opposite the first surface;
one or more fully controlled power semiconductor devices each of which is on the first surface, wherein each fully controlled power semiconductor device includes an electrical control terminal, a first power terminal, and a second power terminal; and
one or more electrical circuits configured to absorb and/or dissipate electrical energy each of which is on the first surface, wherein each electrical circuit configured to absorb and/or dissipate the electrical energy is electrically connected to the first and the second power terminals of a fully controlled power semiconductor device.

2. The lower cost power module with the higher configuration flexibility of claim 1, wherein each electrical circuit configured to absorb and/or dissipate the electrical energy consists of a transient voltage suppressor diode, a metal oxide varistor, an avalanche diode, a Zener diode, and/or a gas discharge tube.

3. The lower cost power module with the higher configuration flexibility of claim 1, wherein the one or more fully controlled power semiconductor devices include a metal oxide semiconductor field effect transistor (MOSFET), an insulated gate bipolar transistor (IGBT), a metal oxide semiconductor controlled thyristor (MCT), a gate turn-off thyristor (GTO), and/or an integrated gate commutate thyristor (IGCT).

4. The lower cost power module with the higher configuration flexibility of claim 1, wherein the polymer-ceramic composite substrate comprises Rogers Corporation RO4350B Laminate.

5. The lower cost power module with the higher configuration flexibility of claim 1, wherein the lower cost power module with the higher configuration flexibility is covered by potting material.

6. The lower cost power module with the higher configuration flexibility of claim 5, wherein the potting material comprises a solid or gelatinous compound.

7. The lower cost power module with the higher configuration flexibility of claim 1, wherein the lower cost power module with the higher configuration flexibility is immersed in liquid insulation material.

8. The lower cost power module with the higher configuration flexibility of claim 7, wherein the liquid insulation material comprises mineral oil.

9. The lower cost power module with the higher configuration flexibility of claim 1, further comprising a heat absorber covering, at least partially, at least one of the one or more fully controlled power semiconductor devices.

10. The lower cost power module with the higher configuration flexibility of claim 9, wherein the heat absorber comprises a phase-change material, a high-specific-heat material, aluminum, and/or molybdenum.

11. The lower cost power module with the higher configuration flexibility of claim 1, further comprising:
another electrical circuit on the second surface; and
an electrically conductive via hole, through the first and the second surfaces, which is configured to electrically connect the other electrical circuit with the fully controlled power semiconductor device and/or with an electrical circuit configured to absorb and/or dissipate the electrical energy.

12. A method of making a lower cost power module with higher configuration flexibility, the method comprising:
mounting, on a first surface of a polymer-ceramic substrate, a fully controlled power semiconductor device;
mounting, on the first surface of the polymer-ceramic substrate, electrical circuitry configured to absorb and/or dissipate electrical energy; and
electrically connecting the fully controlled power semiconductor device to the electrical circuitry configured to absorb and/or dissipate the electrical energy.

13. The method of claim 12, further comprising depositing a heat absorber over at least a portion of at least one fully controlled power semiconductor device.

14. The method of claim 12, further comprising immersing the lower cost power module with the higher configuration flexibility in liquid insulation.

15. The method of claim 12, further comprising:
forming at least one electrically conductive via hole through the polymer-ceramic substrate from the first surface to a second surface of the polymer-ceramic substrate, wherein the first surface is opposite the second surface; and
mounting one or more other electrical circuits on the second surface of the polymer-ceramic substrate, wherein at least one other electrical circuit is electrically connected, through one or more electrically conductive via holes, to the fully controlled power semiconductor device and/or the electrical circuitry configured to absorb and/or dissipate the electrical energy.

16. The method of claim 15, further comprising depositing a heat absorber over at least a portion of at least one fully controlled power semiconductor device.

17. The method of claim 15, further comprising immersing the lower cost power module with the higher configuration flexibility in liquid insulation.

18. The method of claim 15, further comprising:
depositing a heat absorber over at least a portion of at least one fully controlled power semiconductor device;
mounting the polymer-ceramic substrate in at least one housing; and
depositing potting material over at least one side of the polymer-ceramic substrate and components thereon.

19. The method of claim 18, further comprising immersing the lower cost power module with the higher configuration flexibility in liquid insulation.

20. The method of claim 12, wherein electrically connecting the fully controlled power semiconductor device to the electrical circuitry configured to absorb and/or dissipate the electrical energy comprises electrically connecting, with one or more wire bonds and/or bond ribbons, the fully controlled power semiconductor device to the electrical circuitry configured to absorb and/or dissipate the electrical energy.
